(19) United States
(12) Patent Application Publication
(10) Pub. No.: US 2018/0156841 A1
(43) Pub. Date: Jun. 7, 2018

(54) Structure and Method of Making Circuitized Substrate Assembly

(71) Applicant: i3 Electronics, Inc., Binghamton, NY (US)

(72) Inventors: Matthew D. Neely, Endicott, NY (US); John Lauffer, Waverly, NY (US)

(73) Assignee: i3 Electronics, Inc., Binghamton, NY (US)

(21) Appl. No.: 15/370,200

(22) Filed: Dec. 6, 2016

(51) Int. Cl. G01R 1/04; H01L 21/48; H01L 25/065; H01L 25/00; H01L 23/498; G01R 31/28

(52) U.S. Cl. CPC G01R 1/0466; H01L 21/4853; H01L 21/4857; H01L 21/486; G01R 31/2834; H01L 25/50; H01L 23/49833; H01L 23/49827; H01L 25/0655

(57) ABSTRACT

A structure and method for a circuitized substrate assembly that provides interface capability with high-density I/O devices, such as semiconductor devices, said structure and method providing enhanced capability for direct chip attach technology and for device interface board that perform functional and operational testing capability for semiconductor devices having an interconnect pitch down to 50 um or smaller.

### FIELD OF THE INVENTION

This invention relates to circuitized substrates and circuitized substrate assemblies and particularly to those used to achieve the fine circuit density required to enable testing of semiconductor dies and to enable direct chip attach technology.

### BACKGROUND OF THE INVENTION

Multilayered printed circuit boards (PCBs), laminate chip carriers, and the like organic products permit formation of multiple circuits in a minimum volume or space. These typically comprise a stack of electrically conductive layers of signal, ground and/or power planes separated from each other by layers of organic dielectric material. The planes may be in electrical contact with each other by plated holes passing through the dielectric layers. The plated holes are often referred to as “vias” if internally located, “blind vias” if extending a predetermined depth within the board from an external surface, or “plated-thru-holes” (PTHs) if extending substantially through the board's full thickness. By the term “thru-hole” as used herein is meant to include all three types of such board openings.

Today's methods for fabricating such PCBs, chip carriers and the like typically comprise fabrication of separate inner-layer circuits (circuitized layers), which are formed by coating a photosensitive layer or film over a copper layer of a copper clad inner-layer base material bonded (e.g., laminated) to a dielectric layer. The organic photosensitive coating is imaged, developed and the exposed copper is etched to form conductor lines, pads and the like, depending on the desired circuit pattern. After etching, the photosensitive film is stripped from the copper leaving the circuit pattern on the surface of the inner-layer base material. Alternatively, the photosensitive coating can be imaged such that channels are developed, and additively plated to build up a circuit pattern, followed by stripping the photosensitive film, and etching the background copper between circuits. In either case, this processing is referred to as photolithographic processing in the PCB art and further description is not deemed necessary. Following the formation of individual inner-layer circuits, each including at least one conductive layer and supporting dielectric layer, a multilayer “stack” is formed by preparing a lay-up of several inner-layers, ground planes, power planes, etc., typically separated from each other by a dielectric, organic pre-preg typically comprising a layer of glass (typically fiberglass) cloth impregnated with a partially cured material, typically a B-stage epoxy resin. Such an organic material is also referred to as glass reinforced epoxy dielectric material. The glass reinforcement helps to provide greatly improved dimensional stability over the area and volume of the printed circuit board.

The top and bottom outer layers of the stack usually comprise copper clad, glass-filled, epoxy planar substrates with the copper cladding comprising exterior surfaces of the stack. The stack is laminated to form a monolithic structure (PCB, or more generally, circuitized substrate) using heat and pressure to fully cure the B-stage resin. The PCB or circuitized substrate so formed typically has metal (usually copper) cladding on both of its exterior surfaces. Exterior circuit layers are formed in the copper cladding using procedures similar to the procedures used to form the inner-layer circuits. A photosensitive film is applied to the copper cladding and the coating is then exposed to patterned activating radiation and developed. An etching solution such as cupric chloride is then used to remove any copper bared by the development of the photosensitive film. Finally, the remaining photosensitive film is removed to provide the exterior circuit layers. The resulting assembly may include as many as fifty or more conductive layers and a corresponding number of dielectric layers, all laminated into the final stacked assembly in a simultaneous manner using conventional lamination processes.

Glass reinforced epoxy materials suffer from some disadvantages as the dimensions of circuit lines, spaces, and lead-to-lead pitch reduce in scale, particularly as they approach the dimensions required to interface with semiconductor devices. One disadvantage is that the impregnated glass fibers in the dielectric material can form very small diameter capillaries within the glass fiber strands, or between the exterior of the glass fiber strands and the epoxy resin, forming risk sites that can produce shorts between internal conductors during subsequent processing. As the circuitization dimensions become smaller, the likelihood of these risk sites producing internal shorts increases.

Another disadvantage deals with the formation of vias using laser technology. The epoxy resin and glass reinforced fibers that make up typical printed circuit board construction absorb laser energy very differently from one another. As a result, the quality of vias produced at different locations in the circuit board vary dramatically, as the ratio of glass fiber to epoxy resin varies from one location to another. This variability increases as the size of the desired circuitry and associated vias are reduced in size.

One way to address these disadvantages is to use multilayer organic substrate (MOS) materials in the fabrication of a circuitized substrate subassembly. MOS circuitized substrate subassemblies utilize non-continuous glass fiber materials such as Thermount™, metal core, Kapton™, liquid crystal polymer (LCP), resin coated copper (RCC), or homogenous thin glass core. The absence of continuous glass fibers allows for smaller circuitized features, and smaller laser drilled via diameters and via pitch compared to glass-reinforced epoxy resin laminates.

Rather than form a large assembly comprising several individual conductive-dielectric layered members, as described above, it is often desirable to initially form a stacked circuitized substrate “subassembly” including two or more conductive layers and associated dielectric layers, the laminated subassembly including a plurality of conductor pads or lands (e.g., copper) on one or both external surfaces. These pads are often formed using photolithographic processing, as mentioned above. Two or more such subassemblies are then aligned and laminated, using an interim organic pre-preg layer such as described above, to form a final multilayered assembly. Additional individual conductor planes and dielectric layers may be included during the lamination to form even more layers for the final assembly.

### OBJECTS AND SUMMARY OF THE INVENTION

One potentially demanding application for circuitized substrate assemblies is that of a device interface board (DIB), which is used to facilitate electrical testing of semiconductor devices. Device interface boards are typically used in Automated Test Equipment (ATE), and provide a means for the ATE probes, which typically engage the device interface board on one plane or surface of the DIB, to communicate with semiconductor devices that are temporarily mounted on another surface, plane, or area, typically the opposing surface. The device interface board allows the ATE probes, which are limited to a minimum lead-to-lead pitch that is much larger than the interface pitch of the semiconductor devices, to communicate through the device interface board to the semiconductor devices, and thereby test the functional and operational characteristics of the devices. The ATE probe lead-to-lead pitch may be on the order of 0.5 to 1 mm, while the semiconductor device pitch can be an order of magnitude smaller in dimension. As such, the circuit density of the device interface board must be much higher on the device-mounted area of the DIB, requiring more demanding circuitization processes as the layers of the device interface board approach the device-mounted surface.

The instant invention provides a structure intended to achieve interface capability with high-density input/output (I/O) devices, while simultaneously minimizing the cost of manufacturing the high density DIB, by providing modular multilayer organic substrate (MOS) subassemblies for the demanding, high circuit density device-mounted side of the DIB, and further providing a method to perform z-interconnect bonding between these high density MOS subassemblies and a second and/or third layer MOS subassembly or printed wiring board (PWB) to produce the composite DIB structure. The area, number of layers, and circuit design of each modular MOS can be optimized for yield and test at the subassembly level, prior to utilizing z-connect bonding to produce the fully functioning DIB.

The current invention requires at least one circuitized substrate subassembly capable of defining fine line widths and spaces small enough to interface with one or more semiconductor die, or sockets to receive semiconductor die, that will be placed under test. This can be accomplished by manufacturing one or more circuitized substrate subassemblies based on multilayer organic substrate (MOS) materials. Multilayer organic substrates are made on non-continuous glass fiber material (e.g. Thermount, metal core, Kapton, liquid crystal polymer (LCP), RCC, or homogenous glass core). In one variation, a first MOS subassembly would serve to interface with the required set of semiconductor dies on one side (top surface), having an I/O pitch in the range of 50-150 um, and expand the I/O pitch on the bottom surface of the MOS subassembly to a larger value; 200-300 um as an example. A second MOS subassembly would serve to further increase the I/O pitch from, for example, 200-300 um on the top surface to 300-500 um on the bottom surface. An additional subassembly, using either PWB or MOS materials, would serve to expand the pitch from, for example, 300-500 um on the top surface to 500-1000 um on the bottom surface, providing sufficiently large I/O pitch for ATE probes to reliably interface with the bottom surface.

In such a subassembly type of process, it is necessary to provide interconnections between the various subassemblies. This is accomplished in one manner by aligning the respective outer conductor pads on one subassembly with those on another and then bringing the two together using conventional lamination procedures. The two subassemblies are separated before lamination by an interim dielectric layer, preferably a conventional pre-preg. This dielectric serves to insulate various external conductive elements (e.g., signal lines) of one subassembly from another while allowing the designated aligned pairs of conductor pads to mate and form an electrical connection. A conductive paste may be used between the two mating pads to enhance the connection.

For assemblies and subassemblies as defined above, electrically conductive thru-holes (or interconnects) may also be used to electrically connect individual circuit layers and may be of one or more of the three types (buried and blind vias, and PTHs) of connections defined above. If such thru-holes are used, the bare hole walls are usually subjected to at least one pre-treatment step after which the walls of the dielectric material are catalyzed by contact with a plating catalyst and metallized, typically by contact with an electro-less or electrolytic copper plating solution. If the thru-holes are PTHs (those which extend through the entire assembly or subassembly), interconnections are thus formed between selected ones of the circuitized layers. Connectivity between aligned thru-holes of mating subassemblies is accomplished preferably using a conductive paste or the like. Such pastes are known to include a highly conductive metal such as silver in the form of flakes, or transient liquid phase sintered paste such as Ormet 701 available from Ormet Circuit, Inc, having a location in San Diego, Calif.

Another demanding application is direct chip attach of multiple devices for High Performance Computing (HPC), and the structure and methods described herein for device interface boards are also applicable for high performance computing applications requiring direct chip attach to the surface of a circuitized substrate assembly.

In accordance with the present invention there is provided a structure and method for a circuitized substrate assembly that provides interface capability with high-density I/O devices, such as semiconductor devices, said structure and method providing enhanced capability for direct chip attach technology and for device interface board that perform functional and operational testing capability for semiconductor devices having an interconnect pitch down to 50 um or smaller.

It is, therefore, a primary object of the invention to enhance the circuitized substrate assembly art.

It is another object of the invention to enhance the circuitized substrate assembly capability for direct chip attach technology.

It is still another object of the invention to provide a modularized circuitized substrate assembly to enhance the capability of performing testing of semiconductor dies and die sets.

It is an additional object of the invention to provide a modularized circuitized substrate assembly capable of interfacing between ATE test probes and one or more semiconductor devices.

It is a further object of the invention to provide a cost-effective, modular method to produce a modularized circuitized substrate assembly structure capable of interfacing between ATE test probes and one or more semiconductor devices.

### BRIEF DESCRIPTION OF THE DRAWINGS

Various objects, features, and attendant advantages of the present invention will become more fully appreciated as the same becomes better understood when considered in conjunction with the accompanying drawings, in which like reference characters designate the same or similar parts throughout the several views, and wherein:

FIG. 1a is a longitudinal sectional view of a first embodiment of a novel modularized circuitized substrate assembly.

FIG. 1b is a longitudinal sectional view of a second embodiment of a novel modularized circuitized substrate assembly.

FIGS. 2a through 2c show longitudinal sectional views of z-interconnect layers.

FIGS. 3 through 6 show a longitudinal sectional view of a method to join circuitized substrate subassemblies to form a novel modularized circuitized substrate assembly.

FIGS. 7 through 8 show a longitudinal sectional view of an alternate method to join circuitized substrate subassemblies to form a novel modularized circuitized substrate assembly.

FIGS. 9 through 10 show a longitudinal sectional view of a method to join circuitized substrate subassemblies to form an alternate embodiment of a novel modularized circuitized substrate assembly.

### DETAILED DESCRIPTION OF THE PREFERRED EMBODIMENT

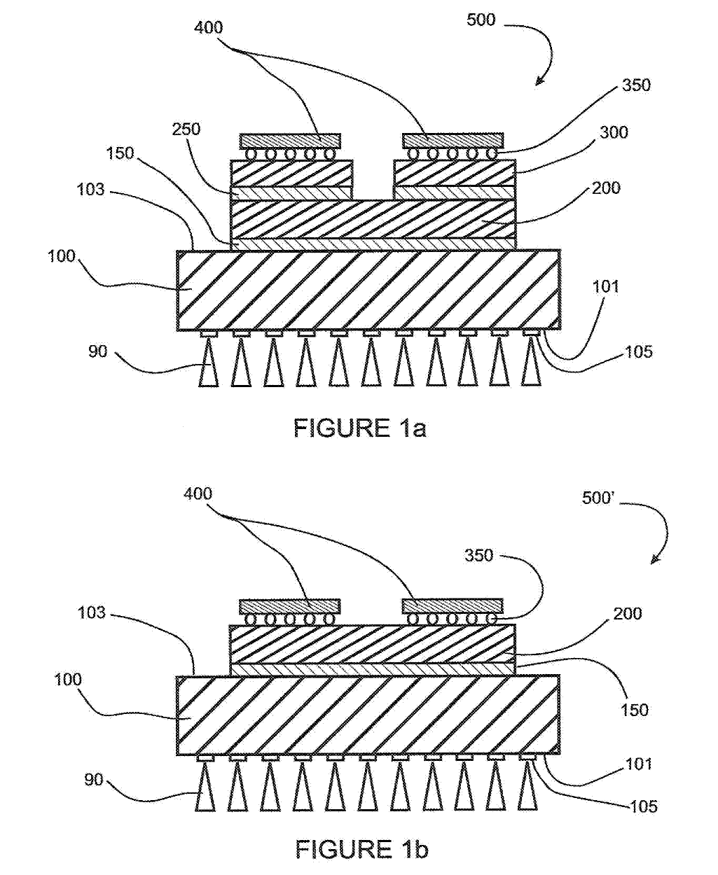

Referring now to the drawings, and, for the present to FIG. 1a, there is shown a longitudinal sectional view of a first embodiment of a novel modularized circuitized substrate assembly (500). In one exemplary application, the modularized circuitized substrate assembly is used to perform functional and operational testing of semiconductor devices and dies, and may be referred to as a device interface board. A device interface board (DIB) is a circuitized substrate assembly designed to provide a means to temporarily mount or attach one or more semiconductor devices at specific sites on the board designed to receive the devices, and provide interconnections to access points that allow automated test equipment to simultaneously contact the board to perform testing of the devices. Device interface boards are necessary because the small lead-to-lead spacing achieved for the Input/Output (I/O) of semiconductor devices precludes the probes of automated test equipment from making direct contact to adjacent I/O sites on the semiconductor devices.

In FIG. 1a, automated test equipment (ATE) probes (90) are shown contacting an array of pads (105) on the first plane (101) of the modularized circuitized substrate assembly (500), opposite the side where the semiconductor devices (400) are mounted. It should be noted that it would also be possible to direct probes to an array of pads on an alternate plane of the modularized circuitized substrate assembly, for example, the second plane (103) of the of first circuitized substrate subassembly (100), hereafter referred to also as the first subassembly, adjacent to the area where the semiconductor devices are received, by altering the circuitry of the first subassembly. In this first embodiment, the first subassembly serves to reduce the lead-to-lead pitch from the dimension needed on the first plane (101) of the first subassembly (100) for accommodating the pitch of the ATE probes (90), to a reduced lead-to-lead pitch on the second plane (103) of the first subassembly (100) between that required by the ATE probes (90) and that required by the semiconductor devices (400). The lead-to-lead pitch on the first plane (101) accommodates contact by ATE probes, and is about 300 microns to about 1000 microns or larger and preferably about 500 microns to about 1000 microns or larger. The lead-to-lead pitch on the second plane (103) is typically from about 200 microns to about 500 microns.

There are at least two reasons why it may be advantageous to reduce the lead-to-lead pitch by a partial amount, rather than attempt to meet the semiconductor device lead-to-lead pitch on the second plane (103).

The first reason is that the most economical material set and processes for production of the first subassembly (100) may not be capable of producing the lead-to-lead pitch required by the semiconductor device at an acceptable yield or quality level. The first subassembly (100) as represented in FIG. 1, may require glass reinforced epoxy material to maintain stable and predictable dimensional stability requirements over the area and volume of the first subassembly. Predictable dimensional stability is desired to ensure that multiple conductive layers within the subassembly maintain alignment with one another, so that reliable interconnections between internal layers can be formed using plated-through holes (PTH's). As described previously, the glass fiber reinforcement has at least two disadvantages as features become smaller—higher risk of producing shorts between internal conductors, formed through or along glass fibers, and high variability in laser ablation of buried and blind vias. These shortcomings are addressed by further aspects of the instant invention.

Secondly, it may be advantageous to design a standardized subassembly for use in many different modularized circuitized substrate assemblies by utilizing the first subassembly (100) as a common base, and employing one or more second circuitized substrate subassemblies (200) and/or one or more third circuitized substrate subassemblies (300) for tailoring the device interface board to specific semiconductor devices. The first subassembly may be produced from standard printed wiring board (PWB) materials and processes described previously in this specification. Additionally, one or more of the subassemblies may be constructed as a multilayer organic substrate (MOS), using one or more non-continuous glass fiber materials, including Thermount™, metal core, Kapton™, liquid crystal polymer (LCP), resin coated copper (RCC), or homogenous thin glass core. These materials can provide higher capability for definition of fine lead-to-lead pitch, but at a premium for cost.

In the instant invention, the second circuitized substrate subassembly (200), hereafter referred to also as the second subassembly, is employed to further reduce the lead-to-lead pitch toward that required for the semiconductor device interface. The second subassembly (200) may also be employed to customize the device interface board to perform testing for a specific semiconductor device or set of devices (400). In the case where testing a set of devices is desired, the second subassembly (200) provides the interconnect circuitry required for the device set to operate and perform testing in concert with one another. Alternatively, the second subassembly (200) provides interconnect for the purpose of individually testing multiple devices, to provide efficiency in those cases where testing of a set of devices in concert is not required. Given that one of the primary functions of the second subassembly (200) is to reduce the lead-to-lead pitch, the second subassembly may have a surface area and perimeter that is significantly smaller than that of the first subassembly, such that the first subassembly (100) may accommodate multiple second subassemblies.

In this first embodiment, the second subassembly is preferably constructed as a multilayer organic substrate (MOS), using non-continuous glass fiber materials, including Thermount™, metal core, Kapton™, LCP, RCC, or homogenous thin glass core. As the circuit and lead-to-lead pitch are reduced, the enhanced capabilities of MOS technology are employed to achieve the desired dimensions at acceptable yields. Simultaneously, the reduced area and perimeter of the second subassembly combined with the associated yield and capabilities serve to benefit the economics of using premium materials.

A first z-interconnect layer (150) is utilized to interconnect the second subassembly (200) to the first subassembly (100), after both subassemblies have been produced and tested, thus helping to ensure the quality and yield of the combined subassemblies.

A third circuitized substrate subassembly (300), hereafter referred to also as the third subassembly, serves to provide the lead-to-lead pitch reduction and interconnect between the second subassembly (200) and the semiconductor device or devices under test (400). The third subassembly (300) may be significantly smaller in area and perimeter compared to the second subassembly (200). Each second subassembly (200) may interface with multiple third subassemblies (300). In this first embodiment the third subassembly is preferably constructed as a multilayer organic substrate (MOS), using non-continuous glass fiber materials, including Thermount™, metal core, Kapton™, LCP, RCC, or homogenous thin glass core. Similarly to the second subassembly, as the circuit and lead-to-lead pitch are further reduced, the enhanced capabilities of MOS technology are employed to achieve the desired dimensions at acceptable yields. The significantly smaller dimensions of the third subassembly and the modular production approach allow for improved management of processing and yield costs over other methods and structures.

A second z-interconnect layer (250) is utilized to interconnect the third subassembly (300) to the second subassembly (200), after both subassemblies have been produced and tested, thus helping to ensure the quality and yield of the combined subassemblies. Interconnect between the third subassembly and the semiconductor devices may be provided through direct contact to the ball grid array (350) on a semiconductor device, or by means of a socket (not shown) designed for that purpose.

While the current embodiment describes a first subassembly, second subassembly, and third subassembly in the structure, it would be possible to extend the structure using the methods disclosed in the instant invention to accommodate additional subassemblies as required to support the functional requirements of the modularized circuitized substrate assembly.

It should be recognized that each circuitized substrate subassembly will typically include many internal conductive layers in addition to the two external layers of pads depicted. Each circuitized substrate subassembly may include from about 2 to 50 or more internal conductive planes, including signal layers, ground planes, and voltage, reference, or power planes.

Referring now also to FIG. 1b, there is shown an alternate embodiment for a modularized circuitized substrate assembly (500′).

In FIG. 1b, automated test equipment (ATE) probes (90) are shown contacting an array of pads (105) on a first plane (101) of the modularized circuitized substrate assembly, opposite the side where the semiconductor devices (400) are mounted. As previously discussed, it would also be possible to direct probes to an array of pads on the same side of the modularized circuitized substrate assembly adjacent to the area where the semiconductor devices are received by altering the circuitry of the first subassembly (100). In this alternate embodiment, the first subassembly (100) serves to reduce the lead-to-lead pitch from the dimension needed on the first plane (101) of the first subassembly for accommodating the pitch of the ATP probes, to a reduced lead-to-lead pitch on the second plane (103) of the first subassembly (100) between that required by the ATE probes (90) and the semiconductor devices (400). In this embodiment, the first subassembly (100) is preferably constructed as a multilayer organic substrate (MOS), using non-continuous glass fiber materials, including Thermount™, metal core, Kapton™, liquid crystal polymer (LCP), RCC, or homogenous thin glass core. These materials can provide higher capability for definition of fine lead-to-lead pitch.

In the instant invention, the second subassembly (200) is employed to further reduce the lead-to-lead pitch to that required for the semiconductor device interface. The second subassembly (200) may also be employed to customize the device interface board (500′) to perform testing for a specific semiconductor device or set of semiconductor devices (400). In the case where testing a set of semiconductor devices is desired, the second subassembly (200) provides the interconnect circuitry required for the set of semiconductor devices (400) to operate and perform testing in concert with one another. Alternatively, the second subassembly (200) provides interconnect for the purpose of individually testing multiple devices, to provide efficiency in those cases where testing of a set of devices in concert is not required. Given that one of the primary functions of the second subassembly (200) is to reduce the lead-to-lead pitch, the second subassembly (200) will frequently have a surface area and perimeter that is significantly smaller than that of the first subassembly (100), such that the first subassembly (100) may accommodate multiple second subassemblies (200).

In this second embodiment, the second subassembly (200) is preferably constructed as a multilayer organic substrate (MOS), using non-continuous glass fiber materials, including Thermount™, metal core, Kapton™, (LCP), RCC, or homogenous thin glass core. As the circuit and lead-to-lead pitch are reduced, the enhanced capabilities of MOS technology can be employed to achieve the desired dimensions at acceptable yields. The reduced area and perimeter of the second subassembly (200) combined with the associated yield and capabilities serve to benefit the economics of using premium materials.

A z-interconnect layer (150) is utilized to interconnect the second subassembly (200) to the first subassembly (100), after both subassemblies have been produced and tested, thus helping to ensure the quality and yield of the combined subassemblies. Interconnect between the second subassembly (200) and the semiconductor devices (400) may be provided through direct contact to the ball grid array (350) on the semiconductor devices (400), or by means of a socket (not shown) designed for that purpose.

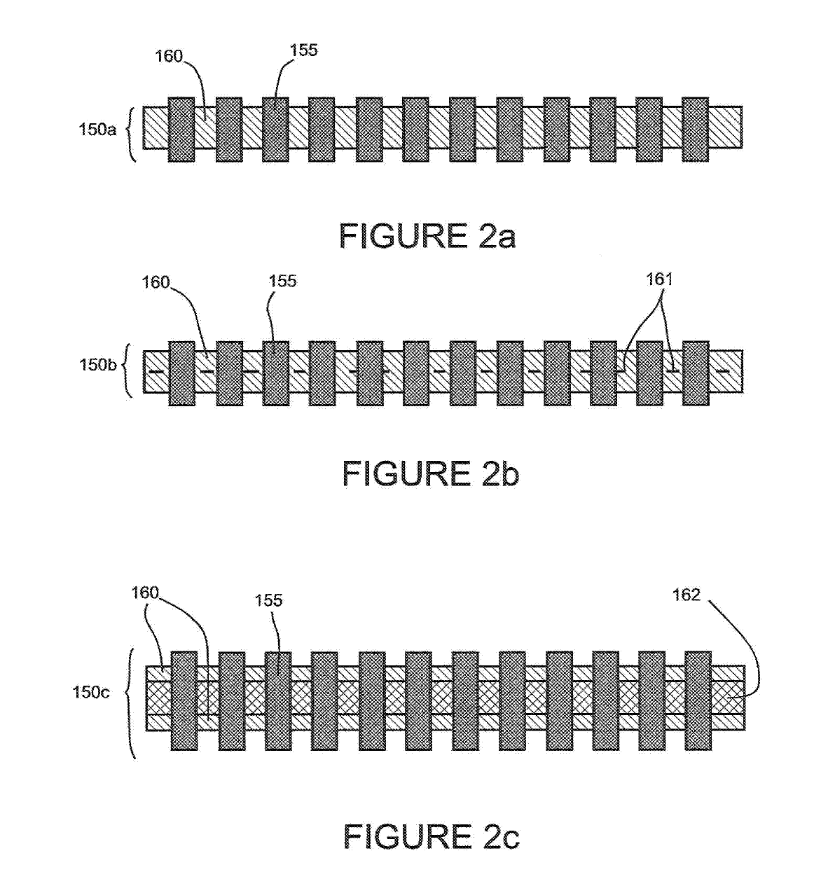

Referring now also to FIG. 2a, there is shown a z-interconnect layer (150a) comprised of a partially cured or b-stage dielectric material (160), having an array of openings that have been subsequently filled with conductive material, each individual such structure defined here as a single z-axis interconnect (155).

Referring now also to FIG. 2b, there is shown an alternate z-interconnect layer (150b) comprised of a conductive layer (161), partially cured or b-stage dielectric material (160) disposed on both sides of the conductive layer, having an array of openings that have been subsequently filled with conductive material, each individual such structure defined here as a single z-axis interconnect (155).

Referring now also to FIG. 2c, there is shown another alternate z-interconnect layer (150c) comprised of a circuitized core (162) comprised of from 2 to 10 or more interconnected conductive layers bonded together with fully cured dielectric material, partially cured or b-stage dielectric material (160) disposed on both sides of the circuitized core, having an array of openings that have been subsequently filled with conductive material, each individual such structure defined here as a single z-axis interconnect (155).

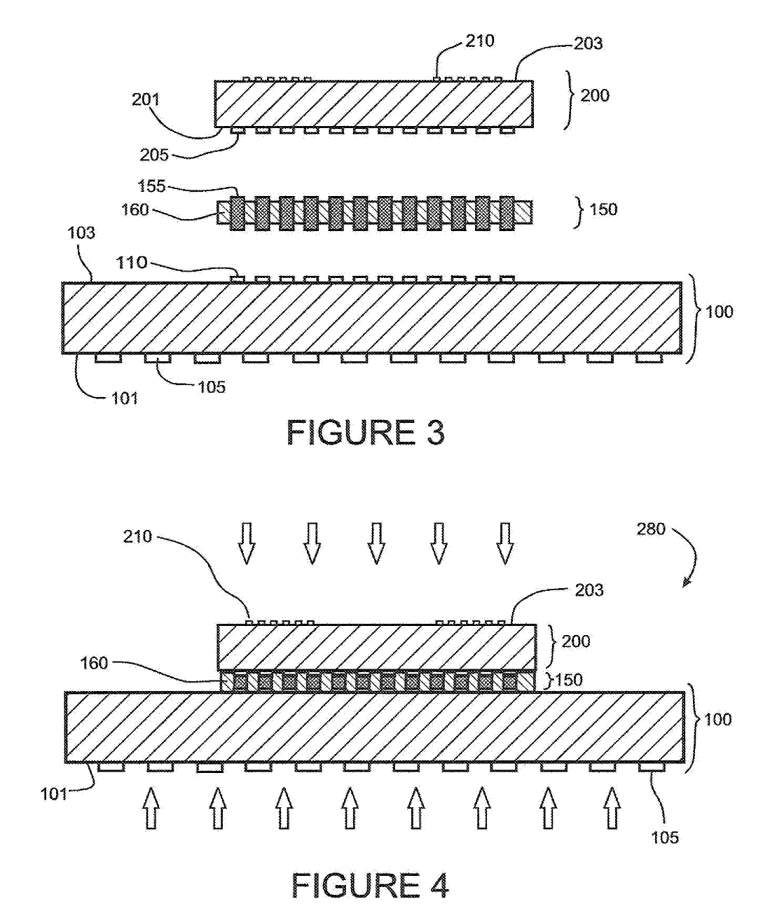

Referring now also to FIG. 3, there is shown a first embodiment comprising a first circuitized substrate subassembly, or first subassembly (100), a first z-interconnect layer (150), and a second circuitized substrate subassembly or second subassembly (200) being prepared for joining. The processes utilized to make the subassemblies and associated circuit patterns are discussed in the specification, and therefore further discussion is not deemed as being required herein. The circuit pattern on the first plane (101) of the first subassembly (100) is at least partially arranged in a grid pattern of contact pads or lands (105) on a pitch designed to reliably align with the mechanical probes of automated test equipment. The arrangement of the contact pads or lands (105) and the corresponding ATE probes (not shown) may be in a square or rectangular grid, or in an interstitial grid pattern, or any other pattern that may be deemed useful for the automated test equipment and for the product under test. The minimum pitch, or distance between adjacent probes, is limited by the physical dimensions of the probes in combination with the electrical requirements of the test being performed, but is about 300 microns to 1000 microns or larger, and preferably about 500 microns to 1000 microns or larger. However, even if tighter pitch is feasible, the need for the instant invention is maintained.

Employing photolithographic processing, and lamination processing described in the specification, the first subassembly is formed with multiple layers (not shown) of internal interconnections between the first plane (101) and second plane (103) thereof. The lead-to-lead pitch of the pads or lands (110) on the second plane (103) of the first subassembly (100) is significantly reduced from that on the first plane (101), to the range of about 200 microns to about 500 microns, and preferably about 300 microns to about 500 microns.

The first z-interconnect layer (150) is comprised of a dielectric material (160), having an array of openings that have been subsequently filled with conductive material, each individual such structure defined here as a single z-axis interconnect (155). The array of z-axis interconnects are produced on the same pitch as the circuit pattern on the second plane (103) of the first subassembly (100), such that, when properly aligned, each z-axis interconnect will engage with the pads or lands (110) on the second plane of the first subassembly. In the preferred embodiment, the dielectric material (160) of the first z-interconnect layer (150) is partially cured, or b-stage, sheet of epoxy glass laminate. The dielectric material (160) could also comprise RCC material, other thermoset or thermoplastic materials. The z-interconnect layer (150) is placed between the first subassembly (100) and second subassembly (200) prior to a lamination step, and the layers are aligned with another in preparation for the lamination step.

The z-interconnect layer (150) may be comprised of any of the z-interconnect alternatives described in FIG. 2a through 2c.

The second subassembly (200) is shown, having an array of pads or lands (205) on the first plane (201) of the second subassembly, produced on the same pitch as pads or lands (110) on the second plane of the first subassembly (110), and the z-axis interconnect (155) of the first z-interconnect layer (150), such that, when it is properly aligned and laminated with the z-interconnect layer (150) and first subassembly (100), a continuous electrical connection is formed from individual pads or lands on the first subassembly (110) through the individual z-axis interconnects (155), to the individual pads or lands on the first plane of the second subassembly (205).

In the first embodiment, the second subassembly is preferably constructed as a multilayer organic substrate (MOS), using non-continuous glass fiber materials, including Thermount™, metal core, Kapton™, liquid crystal polymer (LCP), RCC, or homogenous thin glass core. The second subassembly (200) is formed with internal interconnections between the first plane (201) and second plane (203) of the second subassembly. The lead-to-lead pitch of the pads or lands (210) on the second plane (203) is significantly reduced from that on the first plane (201), preferably to the range of about 200 microns to about 300 microns.

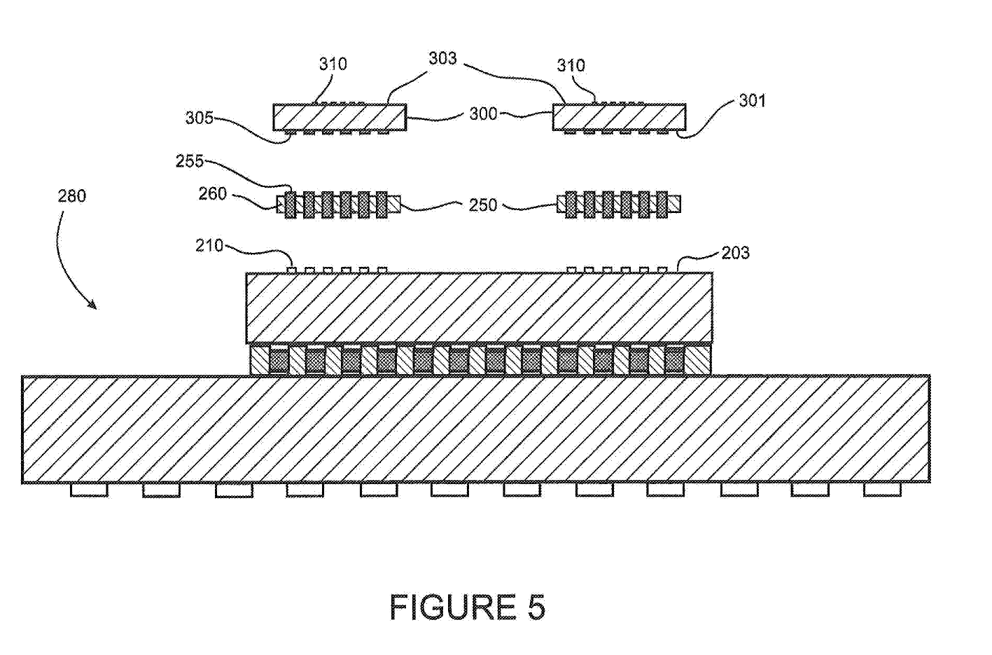

Referring now also to FIG. 4, there is shown a partially completed modularized circuitized substrate assembly (280), having laminated together under elevated heat and pressure, the first subassembly (100), first z-interconnect layer (150), and second subassembly (200). The heat and pressure of the lamination process are sufficient to cause the z-axis interconnects to sinter and/or melt to produce reliable electrical connections between the lands or pads on the second plane of the first subassembly and the lands or pads on the first plane of the second subassembly. In the same lamination process cycle, the dielectric material (160) of the z-interconnect layer (150) re-flows to fill any gaps, and subsequently cures in place, bonding the first subassembly (100) and second subassembly (200) together to form the partially completed modularized circuitized substrate assembly (280).

Referring now also to FIG. 5, there is shown a partially completed modularized circuitized substrate assembly (280), one or more second z-interconnect layers (250), and a corresponding number of third circuitized substrate subassemblies or third subassemblies (300) being prepared for joining.

The second z-interconnect layer (250) is comprised of a dielectric material (260), having an array of openings that have been subsequently filled with conductive material, and defined here as a single z-axis interconnect (255). The array of z-axis interconnects are produced on the same pitch as the pads (210) on the second plane (203) of the second subassembly (now also the top plane of the partially completed modularized circuitized substrate assembly (280)) such that, when properly aligned, each z-axis interconnect will engage with the pads or lands (210) on the second plane of the partially completed device interface board.

The third subassembly (300) is shown, having an array of pads or lands (305) on the first plane (301) of the third subassembly, produced on the same pitch as the z-axis interconnect (255) of the z-interconnect layer (250), such that, when it is properly aligned and laminated with the z-interconnect layer (250) and partially completed device interface board (280), a continuous electrical connection is formed from individual pads or lands on the partially completed device interface board (280) through the individual z-axis interconnects (255), to the individual pads or lands (305) on the first plane (301) of the third subassembly (300). The z-interconnect layer (250) may be comprised of any of the z-interconnect alternatives described in FIG. 2a through 2c.

In the first embodiment, the third subassembly is preferably constructed as a multilayer organic substrate (MOS), using non-continuous glass fiber materials, including Thermount™, metal core, Kapton™, LCP, RCC, or homogenous thin glass core. The third subassembly (300) is formed with internal interconnections between the first plane (301) and second plane (303) thereof. The lead-to-lead pitch of the pads or lands (310) on the second plane (303) is significantly reduced from that on the first plane (301), to provide sufficiently small pitch to accommodate receiving one or more semiconductor devices for testing, preferably in the range of 50 to 150 um.

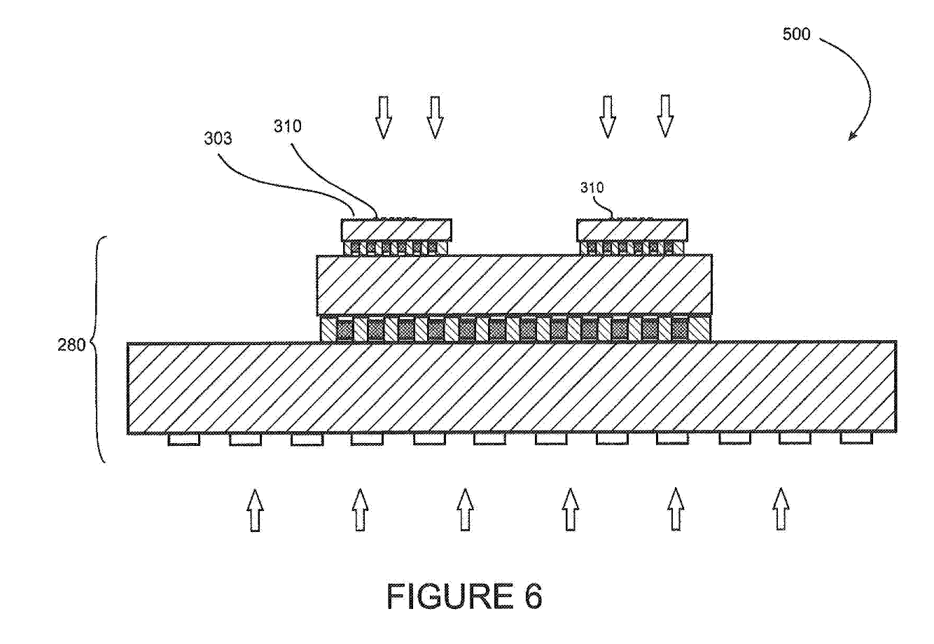

Referring now also to FIG. 6, there is shown a completed first embodiment of a modularized circuitized substrate assembly (500), having been laminated together under elevated heat and pressure, the partially completed device interface board (280), second z-interconnect layers (250), and third subassemblies (300). The heat and pressure of the lamination process are sufficient to cause the z-axis interconnects to sinter and/or melt to produce reliable electrical connections between the lands or pads on the second plane of the first subassembly and the lands or pads on the first plane of the second subassembly. In the same lamination process cycle, the partially cured, or b-stage dielectric (260) of the z-interconnect layer (250) re-flows to fill any gaps, and subsequently cures in place, bonding the partially completed device interface board (280) and third subassemblies (300) together to form the completed device interface board (500).

After completion of the modularized circuitized substrate assembly, interconnect between the third subassembly and the semiconductor devices may be provided through direct contact of pads or lands (310) to the ball grid array on a semiconductor device (not shown), or by means of a socket designed for that purpose.

Direct contact to the device may also be enhanced by the additional step of adding dendritic plating to the surface of the pads or lands (310) on the second surface of the third subassembly (300), now also the top surface of the completed modularized circuitized substrate assembly (500).

Dendrites, formed during dendritic plating, are electro pulse plated palladium/gold, hard velcro-like structures that can break through oxide layers to provide a good, temporary electrical contact under load.

Grey scale etched pads may also be employed for the pads or lands (310) to facilitate the formation of temporary contact between the DIB and semiconductor devices. Grey scale etched, or sculpted pads are formed by selective etch of areas of a pad, resulting in a pad having a central pin surrounded by a bowl or cup shaped pad.

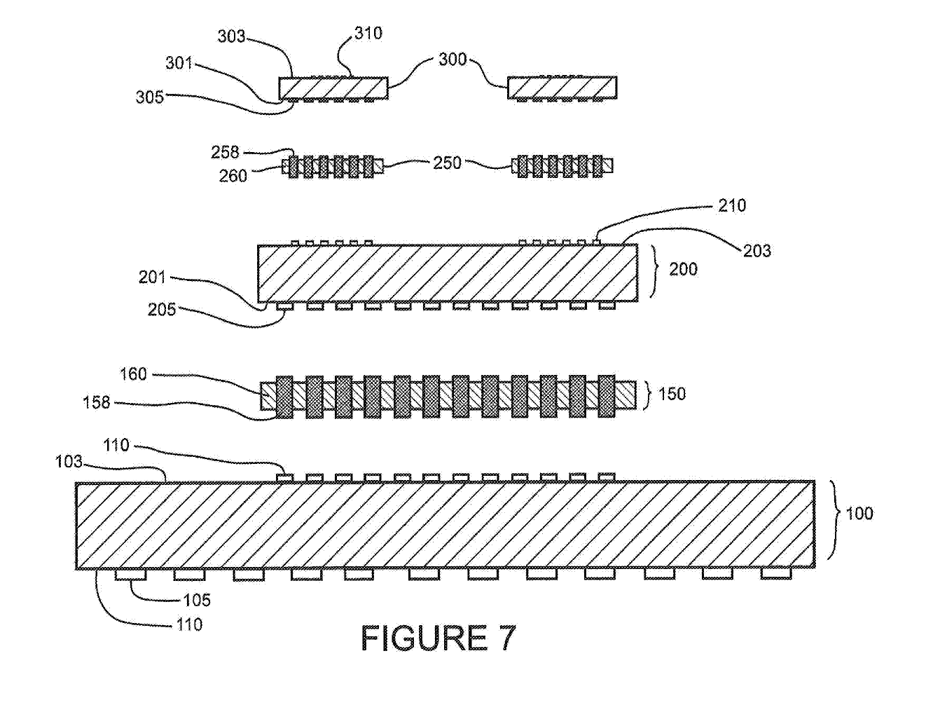

Referring now also to FIG. 7, there is shown an alternate method in which the first subassembly (100), one or more first z-interconnect layers (150), one or more second subassemblies (200), one or more second z-interconnect layers (250) on each second subassembly, and a corresponding number of third subassemblies (300) are simultaneously prepared for joining. The method for joining the subassemblies is the same as previously described for FIG. 3, except that all of the subassemblies and z-interconnect layers are aligned and assembled for joining in a single lamination cycle. The first z-interconnect layer (150) and the one or more second z-interconnect layers (250) may be comprised of any of the z-interconnect alternatives described in FIG. 2a through 2c.

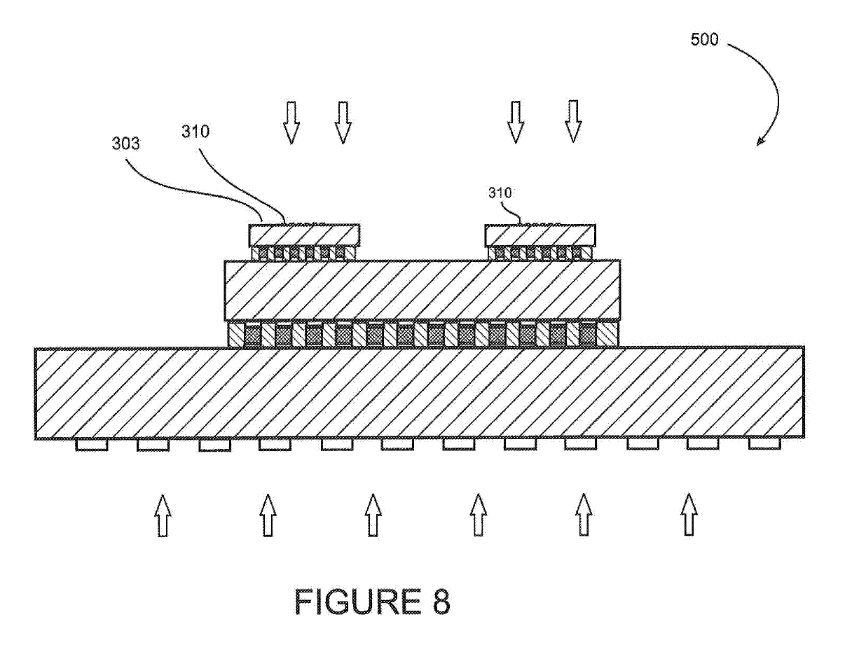

Referring now also to FIG. 8, there is shown a completed first embodiment modularized circuitized substrate assembly (500), having laminated together under elevated heat and pressure, the first, second, and third subassemblies, and first and second z-interconnect layers

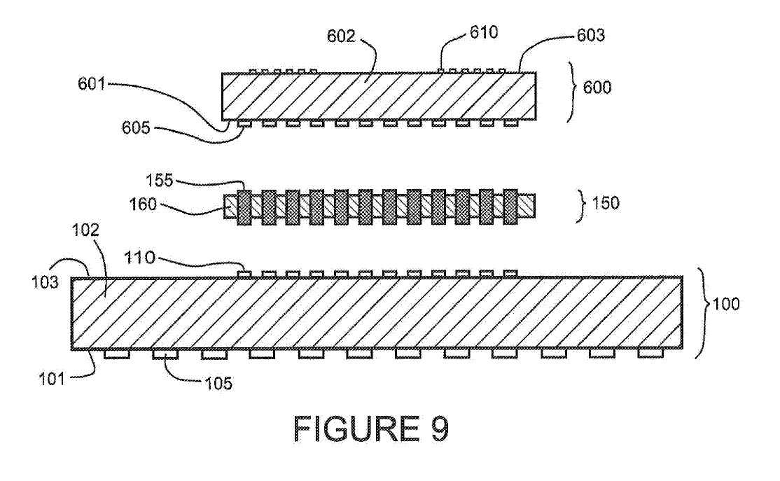

Referring now also to FIG. 9, there is shown a second embodiment comprising a first circuitized substrate subassembly, or first subassembly (100), a first z-interconnect layer (150), and a second circuitized substrate subassembly or second subassembly (600) being prepared for joining. The circuit pattern illustrated on the first plane (101) of the first subassembly (100) is at least partially arranged in a grid pattern of pads or lands on a pitch designed to reliably align with the mechanical probes of automated test equipment. The first subassembly is formed with internal interconnections between the first plane (101) and second plane (103) thereof. The lead-to-lead pitch of the pads or lands (110) on the second plane (103) is significantly reduced from that on the first plane (101), preferably to the range of about 200 microns to about 500 microns. The first z-interconnect layer (150) is comprised of a dielectric material (160), having an array of openings that have been subsequently filled with conductive material, each individual such structure defined here as a single z-axis interconnect (155). The array of z-axis interconnects are produced on the same pitch as the pads or lands (110) on the second plane (103) of the first subassembly (100), such that, when properly aligned, each z-axis interconnect will engage with the pads or lands (110) on the second plane of the first subassembly. The z-interconnect layer (150) may be comprised of any of the z-interconnect alternatives described in FIG. 2a through 2c.

Additionally, the second subassembly (600) is shown, having an array of pads or lands (605) on the first plane (601) of the second subassembly (600), produced on the same pitch as the z-axis interconnect (155) of the first z-interconnect layer (150), such that, when it is properly aligned and laminated with the z-interconnect layer (150) and first subassembly (100), a continuous electrical connection is formed from individual pads or lands on the first subassembly (110) through the individual z-axis interconnects (155), to the individual pads or lands on the first plane (601) of the second subassembly (600). In the alternate embodiment, the second subassembly (600) is preferably constructed as a multilayer organic substrate (MOS), using non-continuous glass fiber materials, including Thermount™, metal core, Kapton™, liquid crystal polymer (LCP), RCC, or homogenous thin glass core. The second subassembly (600) is formed with internal interconnections between the first plane (601) and second plane (603) thereof. The lead-to-lead pitch of the pads or lands (610) on the second plane (603) is significantly reduced from that on the first plane (601), preferably to the range of about 50 to about 300 um to provide interconnect to semiconductor devices or device packages.

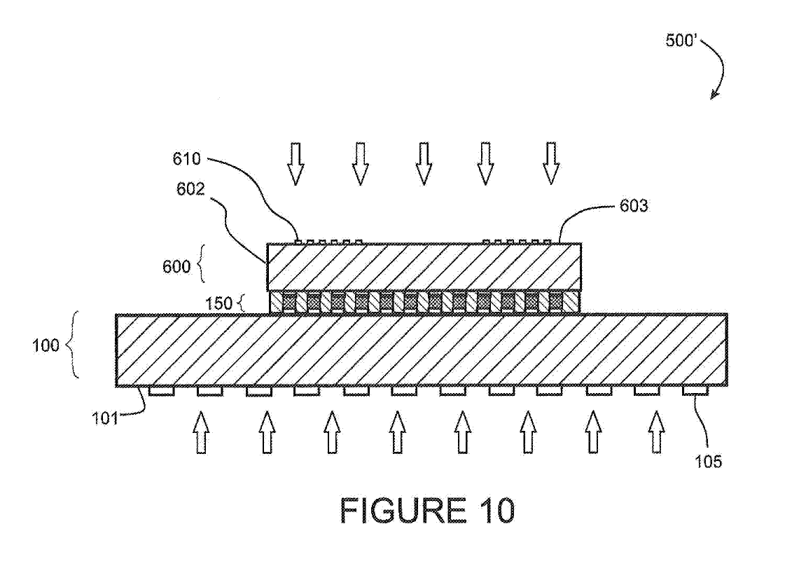

Referring now also to FIG. 10, there is shown a completed device interface board (500′), having laminated together the first subassembly (100), first z-interconnect layer (150), and second subassembly (600).

Since other modifications and changes varied to fit particular operating requirements and environments will be apparent to those skilled in the art, the invention is not considered limited to the example chosen for purposes of disclosure, and covers all changes and modifications which do not constitute departures from the true spirit and scope of this invention.

Having thus described the invention, what is desired to be protected by Letters Patent is presented in the subsequently appended claims.

What is claimed is:

1. A modularized circuitized substrate assembly for interfacing with one or more semiconductor devices or packages comprising:
a first circuitized substrate subassembly having a first array of pads on a first plane, internal interconnections between a first plane and a second plane, said second plane having a second array of pads;
a first z-axis interconnect layer comprised of dielectric and conductive bonding material;
a second circuitized substrate subassembly having a third array of pads on a first plane, internal interconnections between a first plane and a second plane, said second plane having a fourth array of pads;
wherein said third array of pads on said first plane of said second circuitized substrate subassembly and said second array of pads on said second plane of said first circuitized substrate subassembly align with one another.

2. The invention as defined in claim 1, wherein said first circuitized substrate subassembly is composed of either glass reinforced epoxy dielectric, or a multilayer organic substrate materials from the group: Thermount™, metal core, Kapton™, liquid crystal polymer (LCP), RCC, or homogenous thin glass core.

3. The invention as defined in claim 1, said first array of pads on a first plane of said first circuitized substrate subassembly have a pad to pad pitch from about 300 microns to about 1000 microns, and preferably from about 300 microns to about 500 microns.

4. The invention as defined in claim 2, wherein said first array on a first plane of said first circuitized substrate subassembly is designed to interface with automated test equipment probes.

5. The invention as defined in claim 1 wherein said second array of pads on said second plane of said first circuitized substrate subassembly have a pad to pad pitch from about 100 microns to about 500 microns.

6. The invention as defined in claim 1 wherein said conductive material of said z-axis interconnect layer is arranged in a pattern that aligns with said second array of pads on said second plane of said first circuitized substrate subassembly and with said third array of pads on said first plane of said second circuitized substrate subassembly.

7. The invention as defined in claim 1 wherein said second circuitized substrate subassembly is composed of one or more multilayer organic substrate materials from the group: Thermount™, metal core, Kapton™, liquid crystal polymer (LCP), RCC, or homogenous thin glass core.

8. The invention as defined in claim 1 wherein said fourth array of pads on said second plane of said second circuitized substrate subassembly has a pad to pad pitch from about 50 microns to about 300 microns.

9. The invention as defined in claim 8 wherein the said fourth array of pads is designed to accommodate temporary contact to semiconductor devices or packages for the purpose of testing said devices or packages.

10. The invention as defined in claim 8 wherein multiple devices or packages are tested simultaneously.

11. The invention as defined in claim 8 wherein multiple devices or packages are tested as a set.

12. The invention as defined in claim 9 wherein said fourth array of pads further comprises a layer of dendrites on the outer surface of said pads to facilitate contact to said devices or packages.

13. The invention as defined in claim 9 wherein said fourth array of pads further comprises grey scale etched pads to facilitate contact to said devices or packages.

14. The invention as defined in claim 1, further comprising a second z-axis interconnect layer comprised of dielectric and conductive bonding material;
a third circuitized substrate subassembly having a fifth array of pads on a first plane, internal interconnections between a first plane and a second plane, said second plane having a sixth array of pads;
wherein said fifth array of pads on said first plane of said third circuitized substrate subassembly and said fourth array of pads on said second plane of said second circuitized substrate subassembly align with one another.

15. The invention as defined in claim 14, wherein said fourth array of pads on said second plane of said second circuitized substrate subassembly and said fifth array of pads on said first plane of said third circuitized substrate subassembly have a pad to pad pitch from about 200 to about 500 microns.

16. The invention as defined in claim 15 wherein said sixth array of pads on said second plane of said third circuitized substrate subassembly has a pad to pad pitch from about 50 microns to about 300 microns.

17. A method for manufacturing a modularized circuitized substrate assembly for interfacing with one or more semiconductor devices or packages comprising:
aligning a first substrate subassembly together with a z-interconnect layer and one or more second substrate assemblies; and
laminating first substrate subassembly, z-interconnect layer, and second subassemblies under pressure and heat; and
simultaneously bonding subassemblies and melting and sintering a-axis interconnects to pads on first and second substrate subassemblies.

18. The invention as defined in claim 17, wherein pads designed to contact semiconductor devices are subsequently plated with pulse plated palladium/gold dendrites.

19. The invention as defined in claim 17, wherein pads designed to contact semiconductor devices are subsequently selectively etched, resulting in a pad having a central pin surrounded by a bowl or cup shaped pad.
